(19) United States
(12) Patent Application Publication
(10) Pub. No.: US 2008/0007285 A1
(43) Pub. Date: Jan. 10, 2008

(54) Handler and method of testing semiconductor device by means of the handler

(75) Inventors: Masayuki Nakase, Kyoto (JP); Kouji Akahori, Kyoto (JP); Tomohiko Kanemitsu, Osaka (JP); Yasuhiro Kamatani, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/822,219

(22) Filed: Jul. 3, 2007

(30) Foreign Application Priority Data
Jul. 7, 2006 (JP) 2006-187303

(51) Int. Cl. G01R 31/26

(52) U.S. Cl. 324/765

(57) ABSTRACT

An object of the present invention is to provide a handler and a testing method thereof which enable efficient measurements on a plurality of semiconductor devices. An arm control unit 106 controls, for each of contact arms 101a and 101b, the timing of control for performing contact control for bringing semiconductor devices 103a and 103b to be tested to one of a contact state and a non-contact state with test boards 108a and 108b connected to semiconductor testers 109a and 109b. The plurality of semiconductor devices are simultaneously measured using the handler 107, so that when a “defective item” is found on a specific measurement part, only the defective item on the measurement part can be replaced with another untested item and thus tests can be efficiently conducted.

### FIELD OF THE INVENTION

The present invention relates to a handler for transporting and contacting a semiconductor device to be tested to a socket on a test board connected to a semiconductor tester, and transporting the tested semiconductor device to one of a conforming item tray and a non-conforming item tray according to the test result.

### BACKGROUND OF THE INVENTION

In recent years, semiconductor devices have become complicated, the number of pins has increased, and a test time has also increased with the progress of semiconductor-related technology. On the other hand, the prices of semiconductor devices have considerably decreased year by year with a large drop in set prices. Under these circumstances, in order to also reduce test costs in tests on semiconductor devices, it is strongly desired to efficiently test semiconductor devices by connecting a plurality of semiconductor devices to a semiconductor tester. Such a tester is described in Japanese Patent Publication No. 7-52208 and so on.

FIG. 5 shows an example of a conventional handler for simultaneously testing two semiconductor devices 403a and 403b.

Two sockets 404a and 404b are attached to a test board 408 set on a semiconductor tester 409. A handler 407 used for setting, on the sockets 404a and 404b, the semiconductor devices 403a and 403b to be tested and removing the semiconductor devices 403a and 403b therefrom is made up of contact pushers 402a and 402b which can hold the semiconductor devices 403a and 403b on the ends thereof, contact arms 401a and 401b having the contact pushers 402a and 402b attached to the ends thereof, an arm control unit 406 for controlling the ascent and descent of the contact arms 401a and 401b, and a handler interface 405 which is interposed in a signal line between the output of the semiconductor tester 409 and the arm control unit 406 and moves the contact arms 401a and 401b up and down based on the output of the semiconductor tester 409.

The contact arms 401a and 401b are simultaneously moved up and down by the arm control unit 406. Thus the semiconductor devices 403a and 403b held by the contact arms 401a and 401b via the contact pushers 402a and 402b are simultaneously contacted to the sockets 404a and 404b.

After the semiconductor devices 403a and 403b are contacted to the sockets 404a and 404b, a test start signal is transmitted from the handler 407 to the semiconductor tester 409 and the semiconductor devices 403a and 403b are tested by the semiconductor tester 409 through the test board 408.

After the completion of tests on the semiconductor devices 403a and 403b, test results on the semiconductor devices 403a and 403b are transmitted from the semiconductor tester 409 to the handler 407, and the handler 407 having received a transmission result simultaneously removes the semiconductor devices 403a and 403b from the sockets 404a and 404b and transports the semiconductor devices 403a and 403b to one of a conforming item tray and a non-conforming item tray. Semiconductor devices are tested by repeating these operations.

### DISCLOSURE OF THE INVENTION

In the handler 407, the semiconductor devices 403a and 403b are simultaneously set on the sockets 404a and 404b and are simultaneously removed from the sockets 404a and 404b. Thus if the semiconductor device 403a is judged as being a defective item, the semiconductor device 403a cannot be replaced with another untested device until the completion of a test on the other semiconductor device 403b, increasing the test time. Consequently, the test efficiency decreases.

The present invention is designed to solve the aforementioned conventional problem. An object of the present invention is to provide a handler and a testing method thereof which enable efficient measurements on a plurality of semiconductor devices.

A handler according to claim 1 of the present invention includes a plurality of contact arms for bringing semiconductor devices to be tested into contact with test boards connected to semiconductor testers, the handler further including an arm control unit for controlling the plurality of contact arms, wherein the arm control unit controls the timing of control, for each of the contact arms, for performing contact control for bringing the semiconductor devices to be tested to one of a contact state and a non-contact state with the test boards.

A handler according to claim 2 of the present invention includes a plurality of contact arms for bringing semiconductor devices to be tested into contact with test boards connected to semiconductor testers, the handler further including an arm control unit for controlling the plurality of contact arms, wherein the arm control unit controls, for each of the contact arms, a controlled variable of the contact.

A handler according to claim 3 of the present invention, in one of claims 1 and 2, wherein the semiconductor device to be tested is contacted to the test board via a socket provided on the test board.

A handler according to claim 4 of the present invention, in one of claims 1 and 2, wherein the arm control unit transmits a state signal to the semiconductor tester, the state signal indicating the operating state of each of the contact arms.

A handler according to claim 5 of the present invention, in one of claims 1 and 2, wherein the timing of control in one of the contact state and the non-contact state is set at one of the start of a test on the semiconductor device to be tested, the end of the test, and a midpoint of the test based on a test control signal from the semiconductor tester.

A handler according to claim 6 of the present invention, in one of claims 1 and 2, wherein the timing of control for the contact is controlled for each of the contact arms in response to one of a forcing signal for forcibly controlling the contact arms and a test control signal based on one of a start signal and an end signal of each test item.

A handler according to claim 7 of the present invention, in one of claims 1 and 2, wherein the controlled variable of the contact control is one of the pressure and the pressing speed of the contact arm and the controlled variable and the like of the ambient temperature of the semiconductor device.

A method of testing a semiconductor device according to claim 8 of the present invention is a method of testing a semiconductor by means of the handler according to one of claims 1 and 2, and, when a plurality of semiconductor devices are tested using, as a test board, wiring shared among the plurality of semiconductor devices to be tested and wiring making one-to-one connection without being shared among the plurality of semiconductor devices, the method comprises: in a test using the wiring shared among the plurality of semiconductor devices to be tested, transmitting a test control signal from the semiconductor tester to perform control for bringing the semiconductor devices to one of a contact state and a non-contact state, and conducting tests sequentially from the semiconductor devices in the contact state; and in a test using the wiring making one-to-one connection without being shared among the plurality of semiconductor devices, bringing all of the semiconductor devices to be tested to the contact state and conducting simultaneous tests.

A method of testing a semiconductor device according to claim 9 of the present invention is the method of testing a semiconductor device by means of the handler according to one of claims 1 and 2, and comprises: during tests on the plurality of semiconductor devices to be tested, bringing only the semiconductor devices judged as being defective during the tests to a non-contact state; and continuing the tests on the other semiconductor devices to be tested.

A method of testing a semiconductor device according to claim 10 of the present invention is the method of testing a semiconductor device by means of the handler according to one of claims 1 and 2, and comprises: contacting a plurality of semiconductor devices to be tested to test boards to be tested by a semiconductor tester; and changing a pressure applied to the semiconductor device and the test board by a contact arm according to the test result.

A method of testing a semiconductor device according to claim 11 of the present invention is the method of testing a semiconductor device by means of the handler according to one of claims 1 and 2, and comprises: contacting a plurality of semiconductor devices to be tested to test boards to be tested by a semiconductor tester; detecting defects successively occurring on a specific contact position between the semiconductor devices and the test board according to the test result; stopping a subsequent test on the specific contact position; and continuing a test on a contact position other than the specific contact position.

According to this configuration, even when a “defective item” is found among semiconductor devices to be tested, processing on the defective item can be performed for each measurement part. The defective item can be replaced with another untested semiconductor device and the subsequent semiconductor device can be tested at the occurrence of the defect, so that test efficiency improves. Further, it is possible to control the contact pressure and the contact pressing speed of each measurement part based on a test result for each measurement part, so that the optimum contact pressure and contact pressing speed can be set for each measurement part and a test can be more stable.

### BRIEF DESCRIPTION OF THE DRAWINGS

FIG. 1 is a structural diagram of a handler according to First Embodiment of the present invention;

FIG. 2 is an explanatory drawing showing the timing of control of contact arms according to First Embodiment;

FIG. 3 is a structural diagram of a handler according to Third Embodiment of the present invention;

FIG. 4 is a circuit diagram of a test board according to Third Embodiment; and

FIG. 5 is a structural diagram of a conventional handler.

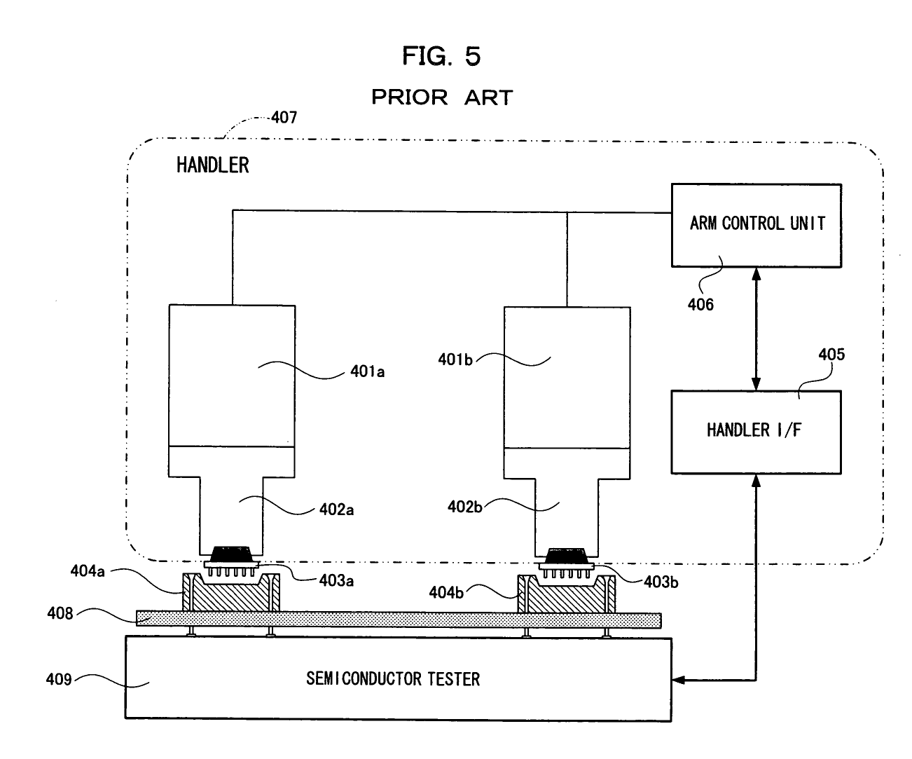

### DESCRIPTION OF THE EMBODIMENTS

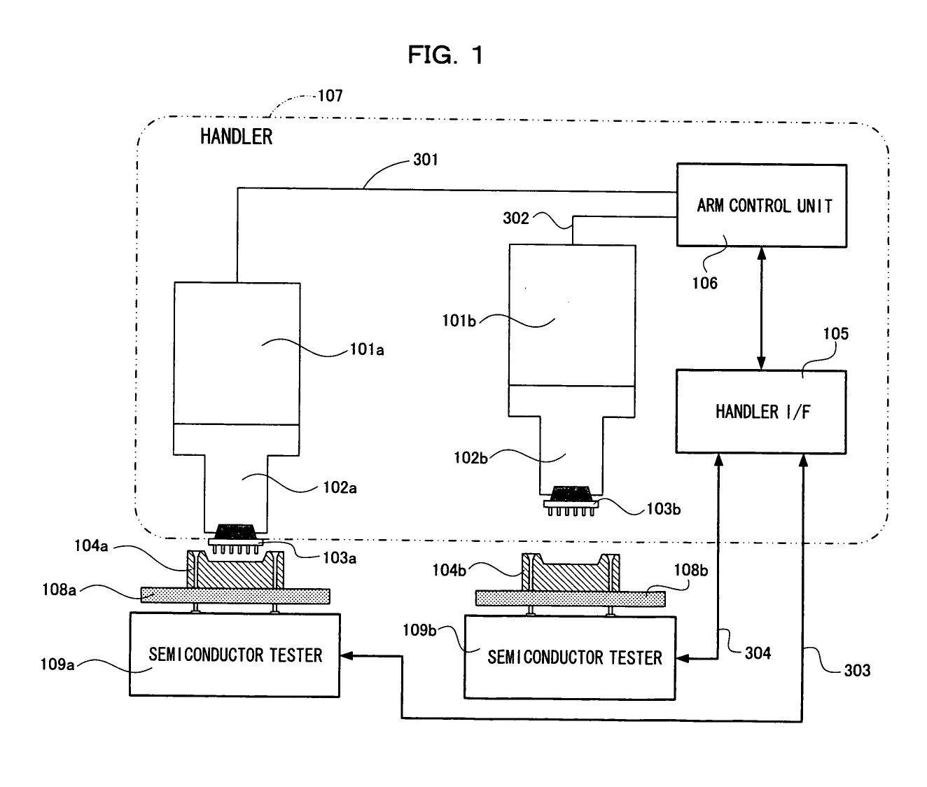

Referring to FIGS. 1 to 4, embodiments of the present invention will now be described below.

### First Embodiment

FIG. 1 shows a handler of First Embodiment.

A handler 107 is made up of two contact arms 101a and 101b, contact pushers 102a and 102b which are attached to the ends of the contact arms 101a and 101b and can hold semiconductor devices 103a and 103b, an arm control unit 106 for controlling the operations of the contact arms 101a and 101b, and a handler interface 105 for converting signals and transferring information between the arm control unit 106 and semiconductor testers 109a and 109b.

The arm control unit 106 separately supplies operation signals to the contact arms 101a and 101b through signal lines 301 and 302 and performs contact control such that the semiconductor devices 103a and 103b to be tested are contacted to a socket 104a on a test board 108a electrically connected to the semiconductor tester 109a and a socket 104b on a test board 18b electrically connected to the semiconductor tester 109b. At this moment, the arm control unit 106 controls the timing of control for each of the contact arms 101a and 101b based on test control signals from the semiconductor testers 109a and 109b and initial settings for the contact arms 101a and 101b. Also when the tested semiconductor devices 103a and 103b are removed and brought to a non-contact state with the sockets 104a and 104b, the arm control unit 106 controls the timing of control for each of the contact arms 101a and 101b based on the test control signals from the semiconductor testers 109a and 109b and the initial settings for the contact arms 101a and 101b.

The following is a specific example in which the timing of control is controlled for each of the contact arms 101a and 101b.

After the handler 107 contacts the semiconductor device 103a to the socket 104a, the arm control unit 106 transmits a test start signal to the semiconductor tester 109a through the handler interface 105. After receiving the test start signal from the arm control unit 106, the semiconductor tester 109a starts a test on the semiconductor device 103a.

After the completion of the test on the semiconductor device 103a, the semiconductor tester 109a transmits the test result to the arm control unit 106 through the handler interface 105. The arm control unit 106 drives the contact arm 101a to transport the tested semiconductor device 103a to one of a conforming item tray and a non-conforming item tray based on the test result on the semiconductor device 103a.

After the handler 107 contacts the semiconductor device 103b to the socket 104b, the arm control unit 106 transmits a test start signal to the semiconductor tester 109b through the handler interface 105. After receiving the test start signal from the arm control unit 106, the semiconductor tester 109b starts a test on the semiconductor device 103b.

After the completion of the test on the semiconductor device 103b, the semiconductor tester 109b transmits the test result to the arm control unit 106 through the handler interface 105. The arm control unit 106 drives the contact arm 101b to transport the tested semiconductor device 103b to one of the conforming item tray and the non-conforming item tray based on the test result on the semiconductor device 103b.

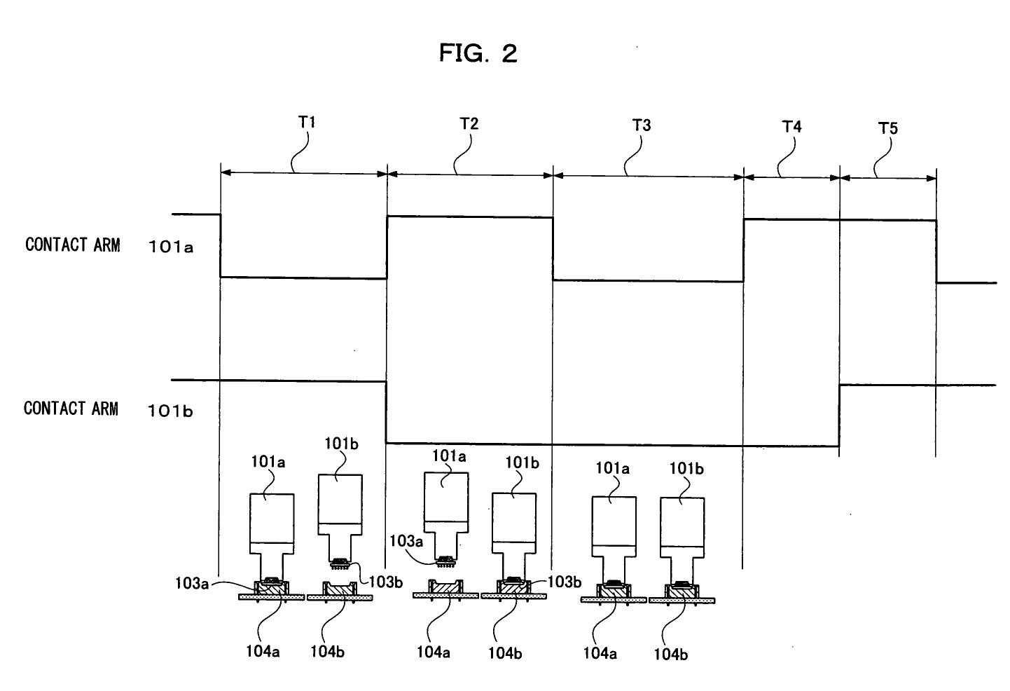

FIG. 2 shows that the contact arms 101a and 101b are changed from an interval T1 in which the contact arm 101a is driven to contact the semiconductor device 103a to the socket 104a but the semiconductor device 103b and the socket 104b are not in contact with each other, to an interval T2 in which the contact arm 101b is driven to contact the semiconductor device 103b to the socket 104b but the semiconductor device 103a and the socket 104a are not in contact with each other, and further to an interval T3 in which the contact arms 101a and 101b are driven to contact the semiconductor device 103a to the socket 104a and contact the semiconductor device 103b to the socket 104b. T4 denotes an interval in which the semiconductor device 103a contacted to the socket 104a is replaced with another by the contact arm 101a. T5 denotes an interval in which the semiconductor device 103b contacted to the socket 104b is replaced with another by the contact arm 101b.

During contact control for bringing the semiconductor devices 103a and 103b to a contact or non-contact state with the sockets 104a and 104b, the arm control unit 106 controls the timing of control for each of the contact arms 101a and 101b. Therefore, by configuring the arm control unit 106 such that a semiconductor device judged as being “defective” according to a test result is immediately replaced with another untested semiconductor device, tests can be more efficiently conducted than the conventional art.

Although the semiconductor devices are contacted to the test boards by using the sockets in the present embodiment, the present invention can be implemented without sockets.

### Second Embodiment

The following is a specific example in which an arm control unit 106 controls the timing of control for each of contact arms 101a and 101b according to First Embodiment.

Second Embodiment describes an example in which the controlled variables of contact arms 101a and 101b are set by the arm control unit 106 from semiconductor testers 109a and 109b through a handler interface 105. In this example, as a controlled variable of the arm, the temperature of a contact is calibrated during a test.

Contact pushers 102a and 102b include heaters serving as heating devices. The temperature of the contact pusher 102a is adjusted to a target temperature by the arm control unit 106 through the contact arm 101a. The temperature of the contact pusher 102b is adjusted to the target temperature by the arm control unit 106 through the contact arm 101b.

When semiconductor devices are tested at a high temperature, in order to more accurately set the temperature of each measurement part by using the temperature characteristics of the semiconductor devices, a test temperature is calibrated for each of the contact pushers 102a and 102b based on a test result made by the semiconductor tester 109a on a semiconductor device 103a and a test result made by the semiconductor tester 109b on a semiconductor device 103b.

That is, temperature characteristic data on the input terminal resistances of the semiconductor devices is obtained beforehand. After a normal test is conducted by a handler 107, the input terminal resistance of a conforming semiconductor device is measured every fixed period of time, the resistance is compared with the previously obtained temperature characteristic data, and a temperature setting signal is transmitted from the semiconductor tester 109a to the arm control unit 106 through the handler interface 105 to perform temperature calibration on the handler. After receiving the temperature setting signal, the handler 107 sets the temperatures of the heaters of the contact pushers 102a and 102b. This operation is performed at regular intervals during the tests on the semiconductor devices, so that the temperature of the measurement part is kept constant.

Further, calibration can be similarly applied to controlled variables such as a pressure on the contact and the pressing speed of the contact in addition to a temperature.

These controlled variables are separately controlled by the arm control unit 106 through the contact arms, so that tests can be properly conducted. To be specific, according to the settings of the controlled variables from the semiconductor testers 109a and 109b to the handler 107, for example, when the controlled variable is the pressing speed of the contact, the pressing speed can be varied between the contact arms 101a and 101b or can be equalized between the contact arms 101a and 101b.

### Third Embodiment

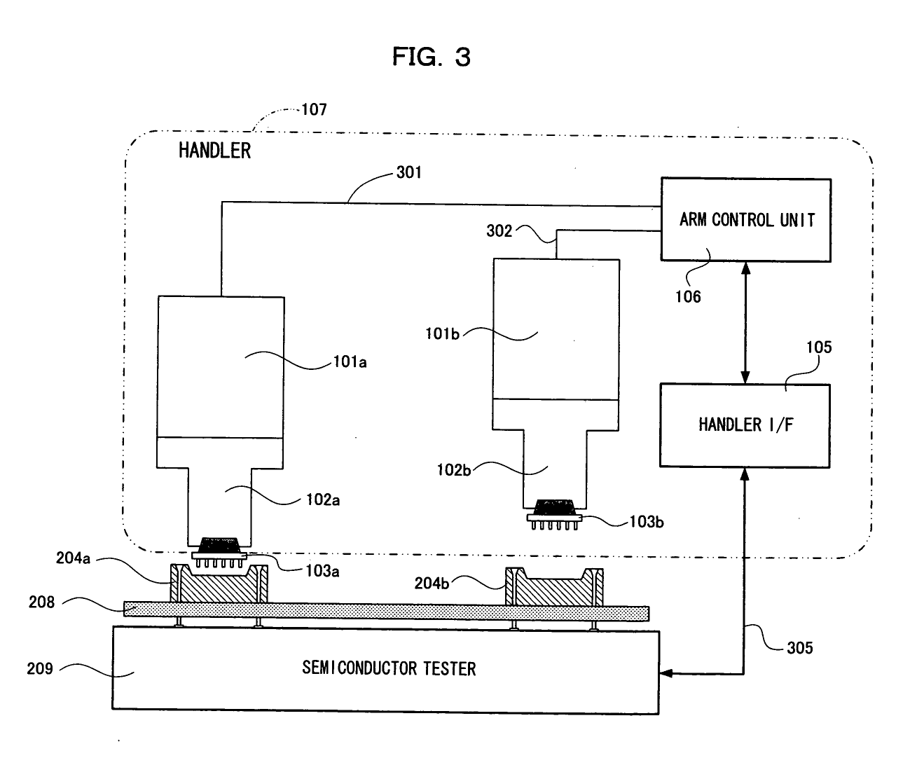

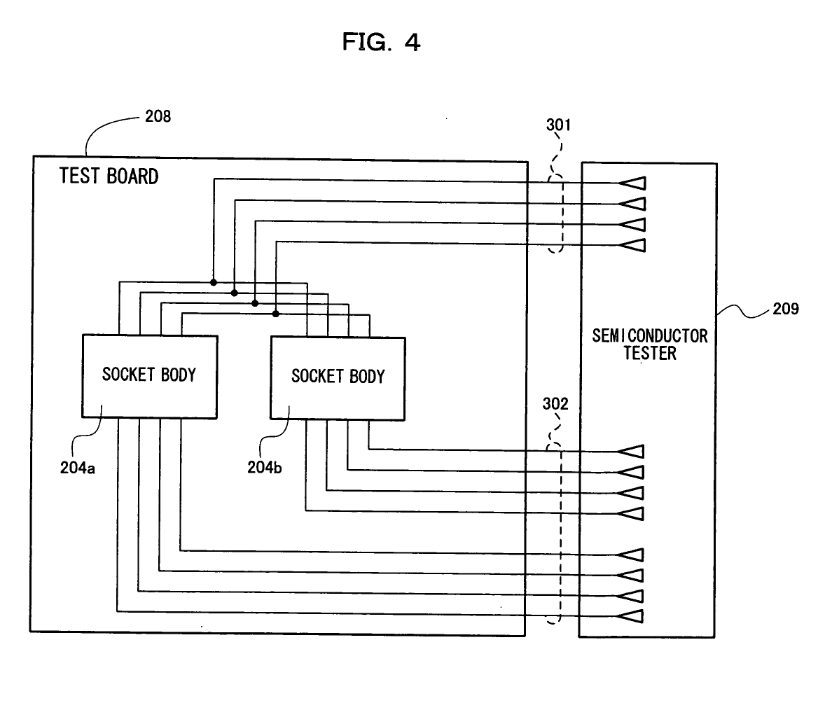

FIGS. 3 and 4 show Third Embodiment of the present invention.

First Embodiment shown in FIG. 1 described the testing method in which the test boards 108a and 108b are electrically connected to the respective semiconductor testers 109a and 109b, and the semiconductor testers 109a and 109b are connected to the handler 107 via signal lines 303 and 304 to transmit and receive signals, so that a test is conducted. In FIG. 3, the handler 107 of First Embodiment is used and a test is conducted using a test board 208 of FIG. 4 instead of the test boards 108a and 108b.

In FIG. 3, although the handler 107 is identical to that of FIG. 1, the test board 208 is electrically connected to a single semiconductor tester 209 and the semiconductor tester 209 is connected to the handler 107 via a signal line 305 to transmit and receive signals.

As shown in FIG. 4, the signal line 305 has signal lines 301 which directly branch to share power supply wiring, ground wiring and the like to a socket 204a and a socket 204b by the tester channel of the semiconductor tester 209 without passing through a relay, and signal lines 302 which are drawn from the sockets 204a and 204b such that the tester channel and the socket make one-to-one wiring for the internal logic of a semiconductor device. In this configuration, semiconductor devices 103a and 103b to be tested are designed for testability such that tests can be conducted with a small number of terminals.

In this testing method, control is performed by an arm control unit 106 to move up and down contact arms 101a and 101b in response to a state signal from the semiconductor tester 209. Next, only the semiconductor device 103a is contacted to the socket 204a in response to the state signal from the handler 107. After that, a test including a contact test and a leakage test (hereinafter, such a test will be referred to as a parametric test) is conducted on the semiconductor device 103a.

Next, an electric signal to the semiconductor device 103a is shut off, the semiconductor device 103a is lifted and brought to a non-contact state with the socket 204a, the semiconductor device 103b is contacted to the socket 204b, and a parametric test is conducted on the semiconductor device 103b.

After that, in a state in which the semiconductor devices 103a and 103b are respectively contacted to the sockets 204a and 204b in response to the state signal from the semiconductor tester 209, logic tests are simultaneously conducted on the semiconductor devices 103a and 103b. With this testing method, it is possible to efficiently conduct a parametric test and a logic test on the semiconductor devices designed for testability.

### Fourth Embodiment

Fourth Embodiment will describe a different testing method from that of Third Embodiment. The handler 107 and the test board 208 of Third Embodiment are used in the present embodiment.

After only the semiconductor device 103a is contacted to the socket 204a in response to the state signal from the handler 107, a parametric test is conducted on the semiconductor device 103a. When the semiconductor device 103a is judged as being “a defective item” in this parametric test, the semiconductor device 103a judged as being “a defective item” is removed, another untested semiconductor device 103a is contacted to the socket 204a, and a parametric test is conducted to confirm whether or not the semiconductor device 103a is a “conforming item”.

Next, an electric signal to the semiconductor device 103a is shut off, the semiconductor device 103a is lifted and brought to a non-contact state with the socket 204a, the semiconductor device 103b is contacted to the socket 204b, and a parametric test is conducted on the semiconductor device 103b. When the semiconductor device 103b is judged as being a “defective item” in this parametric test, the semiconductor device 103b judged as being a “defective item” is removed, another untested semiconductor device 103b is contacted to the socket 204b, and a parametric test is conducted to confirm whether or not the semiconductor device 103b is a “conforming item”.

After that, in a state in which both of the semiconductor devices 103a and 103b are contacted to the sockets 204a and 204b in response to the state signal from the semiconductor tester 209, logic tests are simultaneously conducted on the semiconductor devices 103a and 103b. With this testing method, since a logic test is always conducted on a “conforming item”, it is possible to efficiently conduct a logic test requiring a long test time.

### Fifth Embodiment

Fifth Embodiment will describe a different testing method from that of Third Embodiment. The handler 107 and the test board 208 of Third Embodiment are used in the present embodiment.

After only the semiconductor device 103a is contacted to the socket 204a in response to the state signal from the handler 107, a parametric test is conducted on the semiconductor device 103a. When the semiconductor device 103a is judged as being a “defective item” in the parametric test, the electric signal of the semiconductor device 103a is immediately shut off and the semiconductor device 103a is lifted and brought to a non-contact state with the socket 204a.

Next, the semiconductor device 103b is contacted to the socket 204b and a parametric test is conducted on the semiconductor device 103b.

After that, only the semiconductor device 103b is contacted to the socket 204b in response to the state signal from the semiconductor tester 209, and a function test is conducted on the semiconductor device 103b. With this testing method, even when the test board has shared wiring to the sockets, a test can be conducted without being affected by a defective semiconductor device.

### Sixth Embodiment

In the foregoing embodiments, the semiconductor devices 103a and 103b to be tested are pressed to the sockets with a constant pressure by the contact arms 101a and 101b. The optimum pressure can be set by the following configuration. In the following explanation, Third Embodiment will be described as an example.

The semiconductor device 103a is contacted in response to the state signal from the handler 107 by using the handler 107 of FIG. 3 and the test board 208 of FIG. 4, and then a test is conducted on the semiconductor device 103a. When the semiconductor device 103a is judged as being a “defective item” in this test, the pressure of the contact arm 101a is increased and a test is conducted again by the semiconductor tester 209. By repeating these operations, the optimum pressure of the contact arm 101a is calculated and set.

Next, the semiconductor device 103a is brought to a non-contact state with the socket, the semiconductor device 103b is contacted to the socket 204b, and a test is conducted. At this moment, the pressure of the contact arm 101b is increased or reduced according to a value measured during the test and a test is conducted again by the semiconductor tester 209. By repeating these operations, the optimum pressure of the contact arm 101b is calculated and set. With these operations, the optimum pressure of each contact arm is set, achieving more efficient tests.

### Seventh Embodiment

In the foregoing embodiments, the two contact arms 101a and 101b are separately controlled by the signals from the semiconductor testers, a semiconductor device judged as being a “defective item” according to a test result is, even when the other semiconductor device is being tested, automatically replaced with another untested semiconductor device, and a test is conducted again. In the present embodiment, the semiconductor device 103a is contacted to the socket 104a in the handler 107, and when the semiconductor device 103a is judged as being a “defective item” during a test, another untested semiconductor device 103a is contacted and tested. When the semiconductor device 103a is judged as being a “defective item” also in this test, another untested semiconductor device 103a is contacted and tested. When the semiconductor device 103a is judged as being a “defective item” also in this test, the semiconductor tester 109a decides that a test cannot be conducted on the socket 104a and transmits a signal to the handler 107 to prevent transportation of another semiconductor device to the socket 104a. The handler 107 does not transport another semiconductor device to the socket 104a after receiving the signal, and then a test is conducted only on the other measurement part. With this testing method, the number of retests is reduced, achieving efficient tests.

### Eighth Embodiment

In the foregoing embodiments, the handler 107 is operated in response to designation from the semiconductor tester. In the following explanation, Second Embodiment will be described in detail as an example.

A test program for the test board 208 is loaded into the handler 107 from the semiconductor tester 209. At this moment, information about the measurement parts used for a test is also transferred from the semiconductor tester 209 to the handler 107. The arm control unit 106 of the handler 107 receives the information about the measurement parts and transports a semiconductor device to be tested only to the socket of the necessary measurement part out of the sockets 204a and 204b, and a test is conducted. Other configurations are similar to those of the foregoing embodiments.

According to this configuration, which of the measurement parts should be used for a test is not determined by the handler 107 but can be determined by the semiconductor tester. Thus it is possible to make the most of the functions of the semiconductor tester, improving test efficiency.

In the foregoing embodiments, both of the timing of control and the controlled variables of the plurality of contact arms 101a and 101b are controlled by the arm control unit 106 for each of the contact arms 101a and 101b. Also by controlling one of the timing of control and the controlled variable for each of the contact arms 101a and 101b, a higher degree of effectiveness can be achieved than the conventional art.

The present invention makes it possible to effectively use a tester channel when a plurality of semiconductor device are tested with a handler, thereby improving testing efficiency. Thus the present invention is useful for testing a plurality of small semiconductor devices having a large number of pins.

1. A handler comprising a plurality of contact arms for bringing semiconductor devices to be tested into contact with test boards connected to semiconductor testers, the handler further comprising an arm control unit for controlling the plurality of contact arms,
wherein the arm control unit controls the timing of control, for each of the contact arms, for performing contact control for bringing the semiconductor devices to be tested to one of a contact state and a non-contact state with the test boards.

2. A handler comprising a plurality of contact arms for bringing semiconductor devices to be tested into contact with test boards connected to semiconductor testers, the handler further comprising an arm control unit for controlling the plurality of contact arms,
wherein the arm control unit controls, for each of the contact arms, a controlled variable of the contact.

3. The handler according to claim 1, wherein the semiconductor device to be tested is contacted to the test board via a socket provided on the test board.

4. The handler according to claim 1, wherein the arm control unit transmits a state signal to the semiconductor tester, the state signal indicating an operating state of each of the contact arms.

5. The handler according to claim 1, wherein the timing of control in one of the contact state and the non-contact state is set at one of the start of a test on the semiconductor device to be tested, the end of the test, and a midpoint of the test based on a test control signal from the semiconductor tester.

6. The handler according to claim 1, wherein the timing of control for the contact is controlled for each of the contact arms in response to one of a forcing signal for forcibly controlling the contact arms and a test control signal based on one of a start signal and an end signal of each test item.

7. The handler according to claim 1, wherein the controlled variable of the contact control is one of a pressure and a pressing speed of the contact arm and a controlled variable and the like of an ambient temperature of the semiconductor device.

8. A method of testing a semiconductor device by means of the handler according to claim 1, when a plurality of semiconductor devices are tested using, as a test board, wiring shared among the plurality of semiconductor devices to be tested and wiring making one-to-one connection without being shared among the plurality of semiconductor devices, the method comprising:
in a test using the wiring shared among the plurality of semiconductor devices to be tested, transmitting a test control signal from the semiconductor tester to perform control for bringing the semiconductor devices to one of a contact state and a non-contact state, and conducting tests sequentially from the semiconductor devices in the contact state; and
in a test using the wiring making one-to-one connection without being shared among the plurality of semiconductor devices, bringing all of the semiconductor devices to be tested to the contact state and conducting simultaneous tests.

9. The method of testing a semiconductor device according to claim 8, comprising: during tests on the plurality of semiconductor devices to be tested, bringing only the semiconductor devices judged as being defective during the tests to a non-contact state; and continuing the tests on the other semiconductor devices to be tested.

10. The method of testing a semiconductor device according to claim 8, comprising: contacting a plurality of semiconductor devices to be tested to test boards to be tested by a semiconductor tester; and changing a pressure applied to the semiconductor device and the test board by a contact arm according to the test result.

11. The method of testing a semiconductor device according to claim 8, comprising: contacting a plurality of semiconductor devices to be tested to test boards to be tested by a semiconductor tester; detecting defects successively occurring on a specific contact position between the semiconductor devices and the test board according to the test result; stopping a subsequent test on the specific contact position; and continuing a test on a contact position other than the specific contact position.
